(19) United States
(12) Patent Application Publication
(10) Pub. No.: US 2025/0171628 A1
(43) Pub. Date: May 29, 2025

(54) RESIN COMPOSITION, PREPREG, FILM WITH RESIN, METAL FOIL WITH RESIN, METAL-CLAD LAMINATE, AND WIRING BOARD

(71) Applicant: PANASONIC INTELLECTUAL PROPERTY MANAGEMENT CO., LTD., Osaka (JP)

(72) Inventors: Hirosuke SAITO, Osaka (JP); Hajime OTSUKA, Osaka (JP)

(73) Assignee: PANASONIC INTELLECTUAL PROPERTY MANAGEMENT CO., LTD., Osaka (JP)

(21) Appl. No.: 18/842,659

(22) PCT Filed: Feb. 8, 2023
(86) PCT No.: PCT/JP2023/004122

§ 371 Date: Aug. 29, 2024

(30) Foreign Application Priority Data
Mar. 8, 2022 (JP) 2022-035374

(51) Int. Cl. C08L 39/04; B32B 15/08; B32B 15/20; B32B 37/06; C08J 5/24; C08K 3/36; C08K 5/3437; C09D 139/04

(52) U.S. Cl. CPC C08L 39/04; B32B 15/08; B32B 15/20; B32B 37/06; C08J 5/244; C08K 3/36; C08K 5/3437; C09D 139/04; B32B 2250/05; B32B 2264/1021; B32B 2305/076; B32B 2307/206; B32B 2379/00; C08L 2203/16; C08L 2203/20

(57) ABSTRACT

A resin composition contains a maleimide compound (A) having an arylene structure bonded in meta-orientation in the molecule and a benzoxazine compound (B) having an allyl group in the molecule.

### TECHNICAL FIELD

The present invention relates to a resin composition, a prepreg, a film with resin, a metal foil with resin, a metal-clad laminate, and a wiring board.

### BACKGROUND ART

In various electronic devices, mounting technologies such as higher integration of semiconductor devices to be mounted, higher wiring density, and multi-layering have rapidly progressed along with an increase in the amount of information processed. In addition, wiring boards used in various kinds of electronic equipment are required to be, for example, high-frequency compatible wiring boards such as a millimeter-wave radar board for in-vehicle use. Substrate materials for forming insulating layers of wiring boards used in various kinds of electronic equipment are required to have a low relative dielectric constant and a low dielectric loss tangent in order to increase the signal transmission speed and to decrease the signal transmission loss.

Examples of the substrate materials for forming insulating layers of wiring boards include the resin compositions described in Patent Literatures 1 and 2.

Patent Literature 1 describes a resin composition for printed wiring boards that is a thermosetting resin composition used for forming an insulating layer in a printed wiring board, and contains a maleimide compound, a benzoxazine compound, and an inorganic filler, in which the maleimide compound includes a maleimide compound having a specific structure having an alkylene group in the molecule but not an arylene structure bonded in the meta-orientation. Patent Literature 1 discloses that it is possible to provide a resin composition for printed wiring boards that can realize a printed wiring board having fine circuit dimensions and excellent insulation reliability under high temperature and high humidity conditions.

Patent Literature 2 describes a resin composition containing a modified polyphenylene ether compound having a terminal modified with a substituent having a carbon-carbon unsaturated double bond, a cross-linked curing agent having a carbon-carbon unsaturated double bond in the molecule, and a flame retardant, in which the flame retardant contains a compatible phosphorus compound that is compatible with a mixture of the modified polyphenylene ether compound and the crosslinked curing agent and an incompatible phosphorus compound that is incompatible with the mixture. Patent Literature 2 discloses that it is possible to provide a resin composition that affords a cured product exhibiting excellent heat resistance and flame retardancy as well as maintains the excellent dielectric properties of polyphenylene ether.

### CITATION LIST

### Patent Literatures

Patent Literature 1: JP 2016-196548 A
Patent Literature 2: JP 2015-86330 A

### SUMMARY OF INVENTION

An object of the present invention is to provide a resin composition, which affords a cured product having a low dielectric constant and a low dielectric loss tangent and exhibiting excellent adhesive properties to metal foils and excellent dimensional stability. Another object of the present invention is to provide a prepreg, a film with resin, a metal foil with resin, a metal-clad laminate, and a wiring board, which are obtained using the resin composition.

An aspect of the present invention is a resin composition containing a maleimide compound (A) having an arylene structure bonded in meta-orientation in the molecule and a benzoxazine compound (B) having an allyl group in the molecule.

The object described above and other objects, features and advantages of the present invention will become apparent from the following detailed description and accompanying drawings.

### BRIEF DESCRIPTION OF DRAWINGS

FIG. 1 is a schematic sectional view illustrating an example of a prepreg according to an embodiment of the present invention.

FIG. 2 is a schematic sectional view illustrating an example of a metal-clad laminate according to an embodiment of the present invention.

FIG. 3 is a schematic sectional view illustrating an example of a wiring board according to an embodiment of the present invention.

FIG. 4 is a schematic sectional view illustrating an example of a metal foil with resin according to an embodiment of the present invention.

FIG. 5 is a schematic sectional view illustrating an example of a film with resin according to an embodiment of the present invention.

### DESCRIPTION OF EMBODIMENTS

Metal-clad laminates and metal foils with resin used in the manufacture of wiring boards and the like include not only an insulating layer but also a metal foil on the insulating layer. Wiring boards also include not only an insulating layer but also wiring on the insulating layer. Examples of the wiring include wiring derived from a metal foil equipped in the metal-clad laminate or the like.

In electronic equipment, particularly in small portable devices such as portable communication terminals and notebook computers, diversification, improvement in performance, thinning, and miniaturization have rapidly proceeded. Along with this, in wiring boards used in these products as well, there is a further demand for refinement of conductor wiring, multilayering of conductor wiring layers, thinning, and improvement in performance such as mechanical properties. For this reason, in the wiring boards, it is required that the wirings do not peel off from the insulating layers although provided wirings are refined wirings. In order to meet this requirement, in the wiring boards, it is required that the adhesive properties between wirings and insulating layers are high. Hence, it is required that the adhesive properties between metal foils and insulating layers are high in metal-clad laminates, and substrate materials for forming insulating layers of wiring boards are required to afford cured products exhibiting excellent adhesive properties to metal foils.

Wiring boards and the like used in various kinds of electronic equipment are also required to be hardly affected by changes in the external environment such as being hardly affected by reflow treatment and the like during mounting. For example, wiring boards are required to include insulating layers that are hardly deformed by reflow treatment and the like so that the wiring boards can be used without problems when subjected to reflow treatment as well. In other words, the insulating layers are required to be hardly deformed by temperature changes such as heating during reflow treatment. In particular, as thinning of wiring boards proceeds, problems arise that warping of semiconductor packages in which semiconductor chips are mounted on wiring boards occurs and mounting failures are likely to occur. In order to suppress warping of semiconductor packages in which semiconductor chips are mounted on wiring boards, the insulating layers are required to be hardly deformed by heating. For these reasons, substrate materials for forming insulating layers of wiring boards are required to afford cured products exhibiting excellent dimensional stability so that dimensional changes due to temperature changes less occur.

Furthermore, in order to suppress loss due to increased resistance accompanying refinement of wiring, the insulating layers equipped in wiring boards are required to have a lower relative dielectric constant and a lower dielectric loss tangent.

According to studies by the present inventors, it has been found out that the relative dielectric constant and dielectric loss tangent may be high in a case where a maleimide compound is contained but the maleimide compound is not a maleimide compound having an arylene structure bonded in the meta-orientation in the molecule as the resin composition for printed wiring boards described in Patent Literature 1. It has been found out that the adhesive properties to metal foils and dimensional stability may be insufficient although the dielectric constant and dielectric loss tangent are low in a case where a maleimide compound having an arylene structure bonded in the meta-orientation in the molecule and a benzoxazine compound having an allyl group in the molecule are not contained as the resin composition described in Patent Literature 2. For these reasons, substrate materials of wiring boards and the like are required to afford cured products having a lower dielectric constant and a lower dielectric loss tangent and exhibiting superior adhesive properties to metal foils and superior dimensional stability than the resin compositions described in Patent Literatures 1 and 2.

As a result of extensive studies, the present inventors have found out that the objects such as providing a resin composition, which affords a cured product having a low dielectric constant and a low dielectric loss tangent and exhibiting excellent adhesive properties to metal foils and excellent dimensional stability, are achieved by the present invention below.

Hereinafter, embodiments according to the present invention will be described, but the present invention is not limited thereto.

### [Resin Composition]

A resin composition according to an embodiment of the present invention is a resin composition containing a maleimide compound (A) having an arylene structure bonded in the meta-orientation in the molecule and a benzoxazine compound (B) having an allyl group in the molecule. The resin composition affords a cured product having a low dielectric constant and a low dielectric loss tangent and exhibiting excellent adhesive properties to metal foils and excellent dimensional stability.

### (Maleimide Compound (A))

The maleimide compound (A) is not particularly limited as long as it is a maleimide compound having an arylene structure bonded in the meta-orientation in the molecule. Examples of the arylene structure bonded in the meta-orientation include an arylene structure in which a structure containing a maleimide group is bonded at the meta position (an arylene structure in which a structure containing a maleimide group is substituted at the meta position). The arylene structure bonded in the meta-orientation is an arylene group bonded in the meta-orientation, such as a group represented by the following Formula (6). Examples of the arylene structure bonded in the meta-orientation include m-arylene groups such as a m-phenylene group and a m-naphthylene group, and more specific examples thereof include a group represented by the following Formula (6).

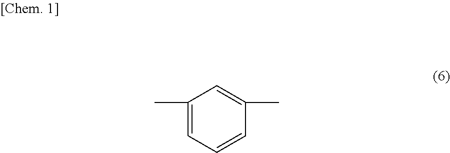

Examples of the maleimide compound (A) include a maleimide compound (A1) represented by the following Formula (1), and more specific examples thereof include a maleimide compound (A2) represented by the following Formula (2).

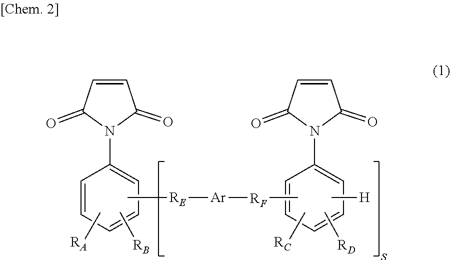

In Formula (1), Ar represents an arylene group bonded in the meta-orientation. R_{A}, R_{B}, R_{C}, and R_{D} are independent of each other. In other words, R_{A}, R_{B}, R_{c}, and R_{D} may be the same group as or different groups from each other. R_{A}, R_{B}, R_{c}, and R_{D} represent a hydrogen atom, an alkyl group having 1 to 5 carbon atoms, or a phenyl group, preferably a hydrogen atom. R_{E} and R_{F} are independent of each other. In other words, R_{E} and R_{F} may be the same group as or different groups from each other. R_{E} and R_{F} represent an aliphatic hydrocarbon group. s represents 1 to 5.

The arylene group is not particularly limited as long as it is an arylene group bonded in the meta-orientation, examples thereof include m-arylene groups such as a m-phenylene group and a m-naphthylene group, and more specific examples thereof include a group represented by Formula (6).

Examples of the alkyl group having 1 to 5 carbon atoms include a methyl group, an ethyl group, a propyl group, an isopropyl group, a n-butyl group, a sec-butyl group, an isobutyl group, a tert-butyl group, a pentyl group, and a neopentyl group.

The aliphatic hydrocarbon group is a divalent group, and may be acyclic or cyclic. Examples of the aliphatic hydrocarbon group include an alkylene group, and more specific examples thereof include a methylene group, a methylmethylene group, and a dimethylmethylene group. Among these, a dimethylmethylene group is preferable.

In the maleimide compound (A1) represented by Formula (1), s, which is the number of repetitions, is preferably 1 to 5. This s is the average value of the number of repetitions (degree of polymerization).

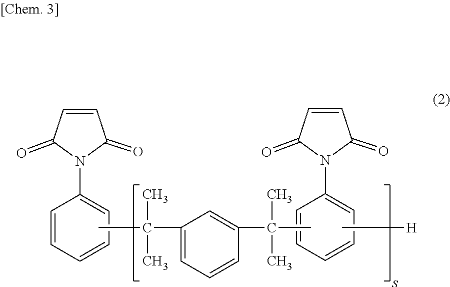

In Formula (2), s represents 1 to 5. This s is the same as s in Formula (1) and is the average value of the number of repetitions (degree of polymerization).

As long as s, which is the average value of the number of repetitions (degree of polymerization), is 1 to 5, the maleimide compound (A1) represented by Formula (1) and the maleimide compound (A2) represented by Formula (2) may include a monofunctional form in which s is 0 or a polyfunctional form such as a heptafunctional form or an octafunctional form in which s is 6 or more.

As the maleimide compound (A), a commercially available product can be used, and for example, the solid component in MIR-5000-60T manufactured by Nippon Kayaku Co., Ltd. may be used.

As the maleimide compound (A), the maleimide compounds exemplified above may be used singly or in combination of two or more kinds thereof. As the maleimide compound (A), the maleimide compound (A1) represented by Formula (1) may be used singly, or two or more different kinds of maleimide compounds (A1) represented by Formula (1) may be used in combination. Examples of the combined use of two or more different kinds of maleimide compounds (A1) represented by Formula (1) include concurrent use of the maleimide compound (A1) represented by Formula (1) other than the maleimide compound (A2) represented by Formula (2) with the maleimide compound (A2) represented by Formula (2).

### (Benzoxazine Compound (B))

The benzoxazine compound (B) is not particularly limited as long as it is a benzoxazine compound having a benzoxazine group in the molecule. Examples of the benzoxazine group include a benzoxazine group represented by the following Formula (3) and a benzoxazine group represented by the following Formula (4). Examples of the benzoxazine compound (B) include a benzoxazine compound (B1) having a benzoxazine group represented by the following Formula (3) in the molecule, a benzoxazine compound (B2) having a benzoxazine group represented by the following Formula (4) in the molecule, and a benzoxazine compound (B3) having a benzoxazine group represented by the following Formula (3) and a benzoxazine group represented by the following Formula (4) in the molecule.

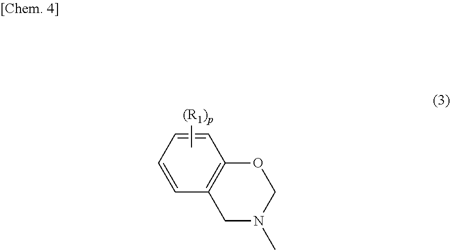

In Formula (3), R₁ represents an allyl group, and p represents 1 to 4. p is the average value of the degree of substitution of R₁, and is 1 to 4, preferably 1.

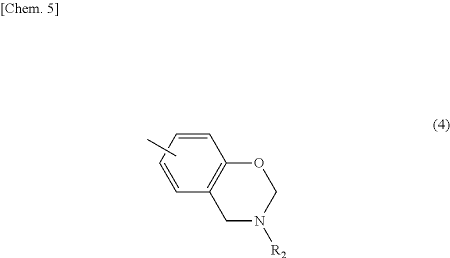

In Formula (4), R₂ represents an allyl group.

As the benzoxazine compound, specifically, the benzoxazine compound (B1) includes a benzoxazine compound (B4) represented by the following Formula (5), and the like, and it is preferable to include this benzoxazine compound (B4).

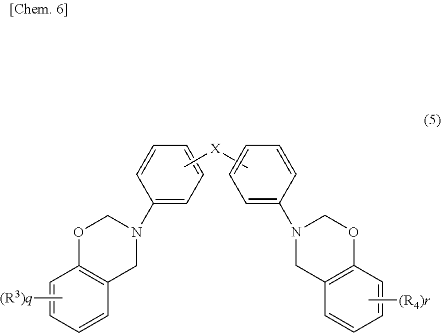

In Formula (5), R₃ and R₄ represent an allyl group, X represents an ether bond (—O—) or an alkylene group, and q and r each independently represent 1 to 4.

The alkylene group is not particularly limited, and examples thereof include a methylene group, an ethylene group, a propylene group, a butylene group, a pentylene group, a hexylene group, a heptylene group, an octane group, an icosane group, and a hexatriacontane group. Among these, a methylene group is preferable.

q is the average value of the degree of substitution of R₃, and is 1 to 4, preferably 1. r is the average value of the degree of substitution of R₄, and is 1 to 4, preferably 1.

As the benzoxazine compound (B), a commercially available product can be used, and for example, ALPd manufactured by SHIKOKU CHEMICALS CORPORATION or the like may be used.

As the benzoxazine compound (B), the benzoxazine compounds exemplified above may be used singly or in combination of two or more kinds thereof. For example, as the benzoxazine compound (B), the benzoxazine compound (B1) having a benzoxazine group represented by Formula (3) in the molecule, the benzoxazine compound (B2) having a benzoxazine group represented by Formula (4) in the molecule, and the benzoxazine compound (B3) having a benzoxazine group represented by Formula (3) and a benzoxazine group represented by Formula (4) in the molecule may each be used singly or may be used in combination of two or more kinds thereof.

### (Styrenic Polymer (C))

The resin composition may further contain a styrenic polymer (C) that is solid at 25° C., and preferably contains the styrenic polymer (C). By containing the styrenic polymer (C), a resin composition can be obtained which becomes a cured product exhibiting superior adhesive properties to metal foils and having a higher Tg. The styrenic polymer (C) is not particularly limited as long as it is a styrenic polymer that is solid at 25° C. Examples of the styrenic polymer (C) include styrenic polymers that are solid at 25° C. and can be used as resins contained in resin compositions used for forming insulating layers equipped in metal-clad laminates, wiring boards, and the like, and the like. The resin compositions used for forming insulating layers of metal-clad laminates, wiring boards and the like may be resin compositions used for forming resin layers of films with resin, metal foils with resin and the like, or may be a resin composition contained in prepregs.

The styrenic polymer (C) is, for example, a polymer obtained by polymerizing a monomer including a styrenic monomer, and may be a styrenic copolymer. Examples of the styrenic copolymer include: copolymers obtained by copolymerizing one or more styrenic monomers and one or more of other monomers copolymerizable with the styrenic monomers. The styrenic copolymer may be a random copolymer or a block copolymer as long as a structure derived from the styrenic monomer is included in the molecule. Examples of the block copolymer include a bipolymer of the structure (repeating unit) derived from the styrenic monomer and the other copolymerizable monomer (repeating unit) and a terpolymer of the structure (repeating unit) derived from the styrenic monomer, the other copolymerizable monomer (repeating unit), and the structure (repeating unit) derived from the styrenic monomer. The styrenic polymer (C) may be a hydrogenated styrenic copolymer obtained by hydrogenating the styrenic copolymer. The styrenic polymer (C) is preferably at least partly hydrogenated. By containing a styrenic polymer that is at least partly hydrogenated, a resin composition can be obtained which becomes a cured product exhibiting superior adhesive properties to metal foils and superior dimensional stability.

The styrenic monomer is not particularly limited, but examples thereof include styrene, a styrene derivative, one in which some hydrogen atoms of the benzene ring in styrene are substituted with an alkyl group, one in which some hydrogen atoms of the vinyl group in styrene are substituted with an alkyl group, vinyltoluene, α-methylstyrene, butylstyrene, dimethylstyrene, and isopropenyltoluene. As the styrenic monomer, these may be used singly or in combination of two or more kinds thereof. The other copolymerizable monomer is not particularly limited, and examples thereof include olefins such as α-pinene, β-pinene, and dipentene, unconjugated dienes such as 1,4-hexadiene and 3-methyl-1,4-hexadiene, and conjugated dienes such as 1,3-butadiene and 2-methyl-1,3-butadiene (isoprene). As the other copolymerizable monomer, these may be used singly or in combination of two or more kinds thereof.

As the styrenic polymer (C), conventionally known ones can be widely used, the styrenic polymer (C) is not particularly limited, but examples thereof include a polymer having a structural unit represented by the following Formula (7) (a structure derived from the styrenic monomer) in the molecule.

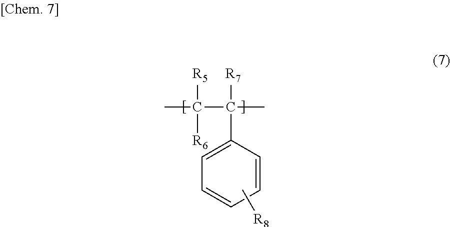

In Formula (7), R₅ to R₇ each independently represent a hydrogen atom or an alkyl group, and R₈ represents any group selected from the group consisting of a hydrogen atom, an alkyl group, an alkenyl group, and an isopropenyl group. The alkyl group is not particularly limited and is, for example, preferably an alkyl group having 1 to 18 carbon atoms and more preferably an alkyl group having 1 to 10 carbon atoms. Specific examples thereof include a methyl group, an ethyl group, a propyl group, a hexyl group, and a decyl group. The alkenyl group is preferably an alkenyl group having 1 to 10 carbon atoms.

The styrenic polymer (C) preferably contains at least one of the structural units represented by Formula (7), and may contain two or more different structural units among those represented by Formula (7) in combination. The styrenic polymer (C) may contain the structural unit represented by Formula (7) and a structural unit other than the structural unit represented by Formula (7) in combination. The styrenic polymer (C) may contain a structure in which the structural unit represented by Formula (7) is repeated.

In addition to the structural unit represented by Formula (7), the styrenic polymer (C) may have at least one among structural units represented by the following Formula (8), the following Formula (9), and the following Formula (10) and structures in which structural units represented by the following Formula (8), the following Formula (9), and the following Formula (10) are each repeated as a structural unit derived from another monomer that is copolymerizable with the styrenic monomer.

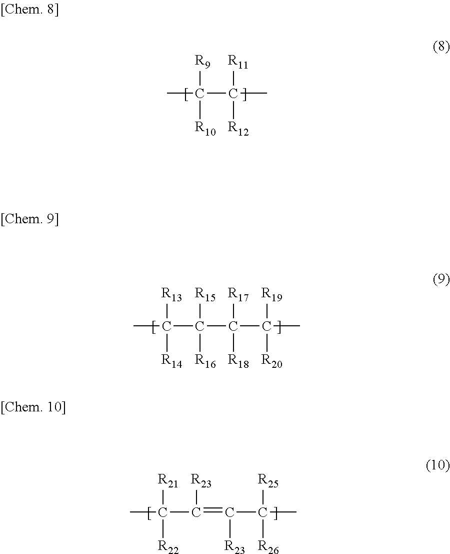

In Formula (8), Formula (9), and Formula (10), R₉ to R₂₆ each independently represent any group selected from the group consisting of a hydrogen atom, an alkyl group, an alkenyl group, and an isopropenyl group. The alkyl group is not particularly limited and is, for example, preferably an alkyl group having 1 to 18 carbon atoms and more preferably an alkyl group having 1 to 10 carbon atoms. Specific examples thereof include a methyl group, an ethyl group, a propyl group, a hexyl group, and a decyl group. The alkenyl group is preferably an alkenyl group having 1 to 10 carbon atoms.

The styrenic polymer (C) preferably contains at least one among the structural units represented by Formula (8), Formula (9), and Formula (10), and may contain two or more different structural units among these in combination. The styrenic polymer may have at least one among the structures in which the structural units represented by Formula (8), Formula (9), and Formula (10) are each repeated.

More specific examples of the structural unit represented by Formula (7) include structural units represented by the following Formulas (11) to (13). The structural unit represented by Formula (7) may be structures in which structural units represented by the following Formulas (11) to (13) are each repeated, and the like. The structural unit represented by Formula (7) may be one structural unit among these or a combination of two or more different structural units.

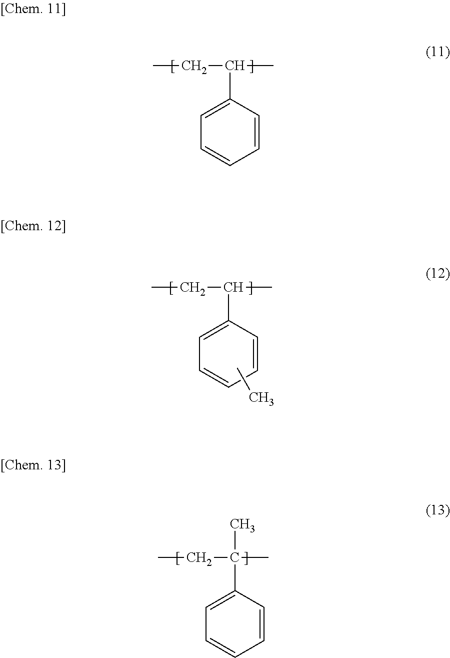

More specific examples of the structural unit represented by Formula (8) include structural units represented by the following Formulas (14) to (20). The structural unit represented by Formula (8) may be structures in which structural units represented by the following Formulas (14) to (20) are each repeated, and the like. The structural unit represented by Formula (8) may be one structural unit among these or a combination of two or more different structural units.

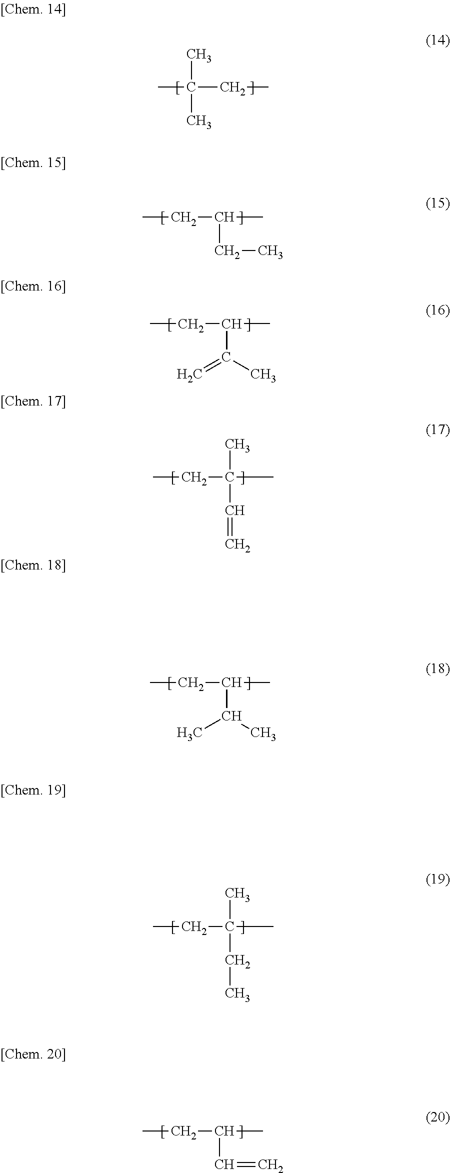

More specific examples of the structural unit represented by Formula (9) include structural units represented by the following Formulas (21) and (22). The structural unit represented by Formula (9) may be structures in which structural units represented by the following Formulas (23) and (24) are each repeated, and the like. The structural unit represented by Formula (9) may be one structural unit among these or a combination of two or more different structural units.

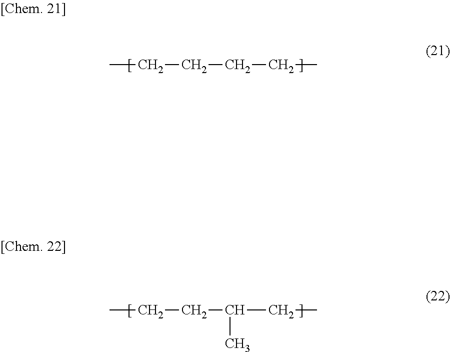

More specific examples of the structural unit represented by Formula (10) include structural units represented by the following Formulas (23) and (24). The structural unit represented by Formula (10) may be structures in which structural units represented by the following Formulas (23) and (24) are each repeated, and the like. The structural unit represented by Formula (10) may be one structural unit among these or a combination of two or more different structural units.

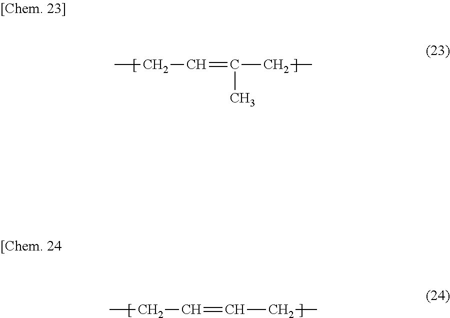

Preferred examples of the styrenic copolymer (C) include polymers or copolymers obtained by polymerizing or copolymerizing one or more styrenic monomers such as styrene, vinyltoluene, α-methylstyrene, isopropenyltoluene, divinylbenzene, or allylstyrene.

More specific examples of the styrenic polymer (C) include a methylstyrene (ethylene/butylene) methylstyrene block copolymer, a methylstyrene (ethylene-ethylene/propylene) methylstyrene block copolymer, a styrene isoprene block copolymer, a styrene isoprene styrene block copolymer, a styrene (ethylene/butylene) styrene block copolymer, a styrene (ethylene-ethylene/propylene) styrene block copolymer, a styrene butadiene block copolymer such as a styrene butadiene styrene block copolymer, a styrene isobutylene styrene block copolymer, a styrene (butadiene/butylene) styrene block copolymer, and hydrogenated products in which these are at least partly hydrogenated.

As the styrenic polymer (C), a commercially available product can be used, and for example, Tuftec P1500, Tuftec H1041, and Tuftec H1517 manufactured by Asahi Kasei Corporation and Asaprene T437 manufactured by Asahi Kasei Corporation may be used.

As the styrenic polymer (C), the styrenic polymers exemplified above may be used singly or in combination of two or more kinds thereof.

The weight average molecular weight of the styrenic polymer (C) is preferably 1,000 to 300,000, more preferably 10,000 to 200,000. When the molecular weight is too low, the glass transition temperature or heat resistance of the cured product of the resin composition tends to decrease. When the molecular weight is too high, the viscosity of the resin composition when prepared in the form of a varnish and the viscosity of the resin composition during heat molding tend to be too high. The weight average molecular weight is only required to be one measured by a general molecular weight measurement method, and specific examples thereof include a value measured by gel permeation chromatography (GPC).

### (Inorganic Filler)

The resin composition may contain an inorganic filler, if necessary, as long as the effects of the present invention are not impaired. It is preferable to contain the inorganic filler from the viewpoint of enhancing the heat resistance and the like of the cured product of the resin composition. The inorganic filler is not particularly limited as long as it is an inorganic filler that can be used as an inorganic filler contained in a resin composition. Examples of the inorganic filler include metal oxides such as silica, alumina, titanium oxide, magnesium oxide and mica, metal hydroxides such as magnesium hydroxide and aluminum hydroxide, talc, aluminum borate, barium sulfate, aluminum nitride, boron nitride, barium titanate, strontium titanate, calcium titanate, magnesium carbonate such as anhydrous magnesium carbonate, and calcium carbonate. Among these, silica, metal hydroxides such as magnesium hydroxide and aluminum hydroxide, aluminum oxide, boron nitride, strontium titanate, calcium titanate, and the like are preferable, and silica is more preferable. The silica is not particularly limited, examples thereof include crushed silica, spherical silica, and silica particles, and spherical silica is preferable.

The inorganic filler may be an inorganic filler subjected to a surface treatment or an inorganic filler not subjected to a surface treatment. Examples of the surface treatment include treatment with a silane coupling agent.

The silane coupling agent is not particularly limited, and examples thereof include a silane coupling agent having at least one functional group selected from the group consisting of a vinyl group, a styryl group, a methacryloyl group, an acryloyl group, a phenylamino group, an isocyanurate group, a ureido group, a mercapto group, an isocyanate group, an epoxy group, and an acid anhydride group. In other words, examples of this silane coupling agent include compounds having at least one of a vinyl group, a styryl group, a methacryloyl group, an acryloyl group, a phenylamino group, an isocyanurate group, a ureido group, a mercapto group, an isocyanate group, an epoxy group, or an acid anhydride group as a reactive functional group, and further a hydrolyzable group such as a methoxy group or an ethoxy group.

Examples of the silane coupling agent include vinyltriethoxysilane and vinyltrimethoxysilane as those having a vinyl group. Examples of the silane coupling agent include p-styryltrimethoxysilane and p-styryltriethoxysilane as those having a styryl group. Examples of the silane coupling agent include 3-methacryloxypropyltrimethoxysilane, 3-methacryloxypropylmethyldimethoxysilane, 3-methacryloxypropyltriethoxysilane, 3-methacryloxypropylmethyldiethoxysilane, and 3-methacryloxypropylethyldiethoxysilane as those having a methacryloyl group. Examples of the silane coupling agent include 3-acryloxypropyltrimethoxysilane and 3-acryloxypropyltriethoxysilane as those having an acryloyl group. Examples of the silane coupling agent include N-phenyl-3-aminopropyltrimethoxysilane and N-phenyl-3-aminopropyltriethoxysilane as those having a phenylamino group.

The average particle size of the inorganic filler is not particularly limited, and is preferably 0.05 to 10 m, more preferably 0.1 to 8 m. Here, the average particle size refers to the volume average particle size. The volume average particle size can be measured by, for example, a laser diffraction method and the like.

### (Content)

The content of the maleimide compound (A) is preferably 50 to 90 parts by mass, more preferably 60 to 85 parts by mass with respect to 100 parts by mass of the sum of the maleimide compound (A) and the benzoxazine compound (B). When the content of the maleimide compound (A) is in the above range, a resin composition can be more suitably obtained which becomes a cured product having a low relative dielectric constant and a low dielectric loss tangent and exhibiting excellent adhesive properties to metal foils and excellent dimensional stability. This is considered to be due to the fact that each of the effect exhibited by containing the maleimide compound (A) and the effect exhibited by containing the benzoxazine compound (B) can be fully exerted when the content of the maleimide compound (A) is in the above range.

The resin composition may contain the styrenic polymer (C) as described above. In a case where the resin composition contains the styrenic polymer (C), the respective contents of the maleimide compound (A), the benzoxazine compound (B), and the styrenic polymer (C) are preferably in the following ranges.

The content of the maleimide compound (A) is preferably 25 to 81 parts by mass, more preferably 30 to 76 parts by mass with respect to 100 parts by mass of the sum of the maleimide compound (A), the benzoxazine compound (B), and the styrenic polymer (C).

The content of the styrenic polymer (C) is preferably 10 to 50 parts by mass, more preferably 15 to 40 parts by mass with respect to 100 parts by mass of the sum of the maleimide compound (A), the benzoxazine compound (B), and the styrenic polymer (C).

The resin composition may contain the inorganic filler as described above. When the resin composition contains the inorganic filler, the content of the inorganic filler is preferably 10 to 150 parts by mass, more preferably 20 to 100 parts by mass with respect to 100 parts by mass of the sum of the maleimide compound (A), the benzoxazine compound (B), and the styrenic polymer (C).

### (Organic Component)

The resin composition according to the present embodiment may contain an organic component other than the maleimide compound (A), the benzoxazine compound (B), and the styrenic polymer (C), if necessary, as long as the effects of the present invention are not impaired. Here, the organic component may or may not react with at least any one of the maleimide compound (A), the benzoxazine compound (B), or the styrenic polymer (C). Examples of the organic component include a maleimide compound (D) different from the maleimide compound (A), a benzoxazine compound (E) different from the benzoxazine compound (B), an epoxy compound, a methacrylate compound, an acrylate compound, a vinyl compound, a cyanate ester compound, an active ester compound, and an allyl compound. In other words, the resin composition may further contain an organic component other than the maleimide compound (A), the benzoxazine compound (B), and the styrenic polymer (C), and the organic component may include at least one selected from the group consisting of a maleimide compound (D) different from the maleimide compound (A), an epoxy compound, a methacrylate compound, an acrylate compound, a vinyl compound, a cyanate ester compound, an active ester compound, and an allyl compound.

The maleimide compound (D) is a maleimide compound that has a maleimide group in the molecule but does not have an arylene structure bonded in the meta-orientation in the molecule. Examples of the maleimide compound (D) include a maleimide compound having one or more maleimide groups in the molecule, and a modified maleimide compound. The maleimide compound (D) is not particularly limited as long as it is a maleimide compound that has one or more maleimide groups in the molecule but does not have an arylene structure bonded in the meta-orientation in the molecule. Examples of the maleimide compound (D) include phenylmaleimide compounds such as 4,4′-diphenylmethane bismaleimide, polyphenylmethane maleimide, m-phenylene bismaleimide, bisphenol A diphenyl ether bismaleimide, 3,3′-dimethyl-5,5′-diethyl-4,4′-diphenylmethane bismaleimide, 4-methyl-1,3-phenylene bismaleimide, and a biphenylaralkyl-type polymaleimide compound, a maleimide compound having an indane structure, and a N-alkylbismaleimide compound having an aliphatic skeleton. Examples of the modified maleimide compound include a modified maleimide compound in which a part of the molecule is modified with an amine compound and a modified maleimide compound in which a part of the molecule is modified with a silicone compound. As the maleimide compound (D), a commercially available product can also be used, and for example, the solid component in MIR-3000-70MT manufactured by Nippon Kayaku Co., Ltd., BMI-4000 and BMI-5100 manufactured by Daiwa Kasei Industry Co., Ltd., and BMI-689., BMI-1500, and BMI-3000J manufactured by Designer Molecules Inc. may be used.

The benzoxazine compound (E) is a benzoxazine compound other than the benzoxazine compound (B) [the benzoxazine compound (B1) (the benzoxazine compound (B4) and the like), the benzoxazine compound (B2), the benzoxazine compound (B3), and the like]. The benzoxazine compound (E) is not particularly limited as long as it is a benzoxazine compound that has a benzoxazine group in the molecule and is other than the benzoxazine compound (B). Examples of the benzoxazine compound (E) include benzoxazine compounds having a phenolphthalein structure in the molecule (phenolphthalein-type benzoxazine compounds), bisphenol F-type benzoxazine compounds, and diaminodiphenylmethane (DDM)-type benzoxazine compounds. More specific examples of the other benzoxazine compound include 3,3′-(methylene-1,4-diphenylene)bis(3,4-dihydro-2H-1,3-benzoxazine) (P-d type benzoxazine compound), 2,2-bis(3,4-dihydro-2H-3-phenyl-1,3-benzoxazine)methane (F-a type benzoxazine compound), and oxydianiline (ODA)-type benzoxazine.

The epoxy compound is a compound having an epoxy group in the molecule, and specific examples thereof include a bisphenol type epoxy compound such as a bisphenol A type epoxy compound, a phenol novolac type epoxy compound, a cresol novolac type epoxy compound, a dicyclopentadiene type epoxy compound, a bisphenol A novolac type epoxy compound, a biphenylaralkyl type epoxy compound, and a naphthalene ring-containing epoxy compound. The epoxy compound also includes an epoxy resin, which is a polymer of each of the epoxy compounds.

The methacrylate compound is a compound having a methacryloyl group in the molecule, and examples thereof include a monofunctional methacrylate compound having one methacryloyl group in the molecule and a polyfunctional methacrylate compound having two or more methacryloyl groups in the molecule. Examples of the monofunctional methacrylate compound include methyl methacrylate, ethyl methacrylate, propyl methacrylate, and butyl methacrylate. Examples of the polyfunctional methacrylate compound include dimethacrylate compounds such as tricyclodecanedimethanol dimethacrylate (DCP).

The acrylate compound is a compound having an acryloyl group in the molecule, and examples thereof include a monofunctional acrylate compound having one acryloyl group in the molecule and a polyfunctional acrylate compound having two or more acryloyl groups in the molecule. Examples of the monofunctional acrylate compound include methyl acrylate, ethyl acrylate, propyl acrylate, and butyl acrylate. Examples of the polyfunctional acrylate compound include diacrylate compounds such as tricyclodecanedimethanol diacrylate.

The vinyl compound is a compound having a vinyl group in the molecule, and examples thereof include a monofunctional vinyl compound (monovinyl compound) having one vinyl group in the molecule and a polyfunctional vinyl compound having two or more vinyl groups in the molecule. Examples of the polyfunctional vinyl compound include divinylbenzene, a curable polybutadiene having a carbon-carbon unsaturated double bond in the molecule, a butadiene-styrene copolymer other than the styrenic polymer, a polyphenylene ether compound having a vinylbenzyl group (ethenylbenzyl group) at the terminal, and modified polyphenylene ether obtained by modifying the terminal hydroxyl group of polyphenylene ether with a methacryl group. Examples of the butadiene-styrene copolymer other than the styrenic polymer include a curable butadiene-styrene copolymer having a carbon-carbon unsaturated double bond in the molecule and being liquid at 25° C., a curable butadiene-styrene random copolymer having a carbon-carbon unsaturated double bond in the molecule, and a curable butadiene-styrene random copolymer having a carbon-carbon unsaturated double bond in the molecule and being liquid at 25° C.

The cyanate ester compound is a compound having a cyanato group in the molecule, and examples thereof include 2,2-bis(4-cyanatophenyl)propane, bis(3,5-dimethyl-4-cyanatophenyl)methane, and 2,2-bis(4-cyanatophenyl)ethane.

The active ester compound is a compound having an ester group exhibiting high reaction activity in the molecule, and examples thereof include a benzenecarboxylic acid active ester, a benzenedicarboxylic acid active ester, a benzenetricarboxylic acid active ester, a benzenetetracarboxylic acid active ester, a naphthalenecarboxylic acid active ester, a naphthalenedicarboxylic acid active ester, a naphthalenetricarboxylic acid active ester, a naphthalenetetracarboxylic acid active ester, a fluorenecarboxylic acid active ester, a fluorenedicarboxylic acid active ester, a fluorenetricarboxylic acid active ester, and a fluorenetetracarboxylic acid active ester.

The allyl compound is a compound having an allyl group in the molecule, and examples thereof include a triallyl isocyanurate compound such as triallyl isocyanurate (TAIC), a diallyl bisphenol compound, an allyl epoxy compound, and diallyl phthalate (DAP).

As the organic component, the organic components described above may be used singly or in combination of two or more kinds thereof.

The weight average molecular weight of the organic component is not particularly limited, and is, for example, preferably 100 to 5000, more preferably 100 to 4000, still more preferably 100 to 3000. When the weight average molecular weight of the organic component is too low, there is a risk that the organic component easily volatilizes from the blended component system of the resin composition. When the weight average molecular weight of the organic component is too high, the viscosity of the varnish of the resin composition and the melt viscosity at the time of heat molding become too high, and there is a risk of deterioration in appearance and moldability when the resin composition is brought into B stage. Hence, a resin composition imparting superior heat resistance and moldability to its cured product is obtained when the weight average molecular weight of the organic component is in such a range. It is considered that this is because the resin composition can be suitably cured. Here, the weight average molecular weight may be measured by a general molecular weight measurement method, and specific examples thereof include a value measured by gel permeation chromatography (GPC).

In the organic component, the average number (number of functional groups) of the functional groups, which contribute to the reaction during curing of the resin composition, per one molecule of the organic component varies depending on the weight average molecular weight of the organic component but is, for example, preferably 1 to 20, more preferably 2 to 18. When this number of functional groups is too small, sufficient heat resistance of the cured product tends to be hardly attained. When the number of functional groups is too large, the reactivity is too high and, for example, troubles such as a decrease in the storage stability of the resin composition or a decrease in the fluidity of the resin composition may occur.

### (Other Components)

The resin composition may contain components (other components) other than the maleimide compound (A) and the benzoxazine compound (B) as long as the effects of the present invention are not impaired. As described above, the resin composition may contain the styrenic polymer (C), the inorganic filler, and the organic component as the other components. Examples of the other components other than the styrenic polymer (C), the inorganic filler, and the organic component include additives such as a flame retardant, a reaction initiator, a curing accelerator, a catalyst, a polymerization retarder, a polymerization inhibitor, a dispersant, a leveling agent, a coupling agent, an antifoaming agent, an antioxidant, a heat stabilizer, an antistatic agent, an ultraviolet absorber, a dye or a pigment, and a lubricant.

As described above, the resin composition according to the present embodiment may contain a flame retardant. The flame retardancy of a cured product of the resin composition can be enhanced by containing a flame retardant. The flame retardant is not particularly limited. Specifically, in the field in which halogen-based flame retardants such as bromine-based flame retardants are used, for example, ethylenedipentabromobenzene, ethylenebistetrabromoimide, decabromodiphenyloxide, and tetradecabromodiphenoxybenzene that have a melting point of 300° C. or more, and a bromostyrene-based compound that reacts with the polymerizable compound are preferable. It is considered that the elimination of halogen at a high temperature and the decrease in heat resistance can be suppressed by the use of a halogen-based flame retardant. There is a case where a flame retardant containing phosphorus (phosphorus-based flame retardant) is used in fields required to be halogen-free. The phosphorus-based flame retardant is not particularly limited, and examples thereof include a phosphate ester-based flame retardant, a phosphazene-based flame retardant, a bis(diphenylphosphine oxide)-based flame retardant, a 9,10-dihydro-9-oxa-10-phosphaphenanthrene-10-oxide (DOPO)-based flame retardant, and a phosphinate salt-based flame retardant. Specific examples of the phosphate ester-based flame retardant include a condensed phosphate ester such as dixylenyl phosphate. Specific examples of the phosphazene-based flame retardant include phenoxyphosphazene. Specific examples of the bis(diphenylphosphine oxide)-based flame retardant include xylylenebis(diphenylphosphine oxide). Specific examples of the DOPO-based flame retardant include hydrocarbons having two DOPO groups in the molecule (DOPO derivative compounds). Specific examples of the phosphinate-based flame retardant include metal phosphinates such as an aluminum dialkyl phosphinate. As the flame retardant, the respective flame retardants exemplified may be used singly or in combination of two or more kinds thereof.

As described above, the resin composition according to the present embodiment may contain a reaction initiator. The reaction initiator is not particularly limited as long as it can promote the curing reaction of the resin composition, and examples thereof include a peroxide and an organic azo compound. Examples of the peroxide include α,α′-di(t-butylperoxy)diisopropylbenzene (PBP), 2,5-dimethyl-2,5-di(t-butylperoxy)-3-hexyne, and benzoyl peroxide. Examples of the organic azo compound include azobisisobutyronitrile. A metal carboxylate can be concurrently used if necessary. By doing so, the curing reaction can be further promoted. Among these, α,α′-di(t-butylperoxy)diisopropylbenzene is preferably used. α,α′-Di(t-butylperoxy)diisopropylbenzene has a relatively high reaction initiation temperature and thus can suppress the promotion of the curing reaction at the time point at which curing is not required, for example, at the time of prepreg drying, and can suppress a decrease in storage stability of the resin composition. α,α′-Di(t-butylperoxy)diisopropylbenzene exhibits low volatility, and thus does not volatilize at the time of prepreg drying and storage, and exhibits favorable stability. The reaction initiators may be used singly or in combination of two or more kinds thereof.

As described above, the resin composition according to the present embodiment may contain a curing accelerator. The curing accelerator is not particularly limited as long as it can promote the curing reaction of the resin composition. Specific examples of the curing accelerator include imidazoles and derivatives thereof, organophosphorus compounds, amines such as secondary amines and tertiary amines, quaternary ammonium salts, organoboron compounds, and metal soaps. Examples of the imidazoles include 2-ethyl-4-methylimidazole (2E4MZ), 2-methylimidazole, 2-phenyl-4-methylimidazole, 2-phenylimidazole, and 1-benzyl-2-methylimidazole. Examples of the organophosphorus compounds include triphenylphosphine, diphenylphosphine, phenylphosphine, tributylphosphine, and trimethylphosphine. Examples of the amines include dimethylbenzylamine, triethylenediamine, triethanolamine, and 1,8-diaza-bicyclo(5,4,0)undecene-7 (DBU). Examples of the quaternary ammonium salts include tetrabutylammonium bromide. Examples of the organoboron compounds include tetraphenylboron salts such as 2-ethyl-4-methylimidazole-tetraphenylborate and tetra-substituted phosphonium/tetra-substituted borate such as tetraphenylphosphonium/ethyltriphenylborate. The metal soap refers to a fatty acid metal salt, and may be a linear fatty acid metal salt or a cyclic fatty acid metal salt. Specific examples of the metal soaps include linear aliphatic metal salts and cyclic aliphatic metal salts having 6 to 10 carbon atoms. More specific examples thereof include aliphatic metal salts formed from linear fatty acids such as stearic acid, lauric acid, ricinoleic acid, and octylic acid and cyclic fatty acids such as naphthenic acid and metals such as lithium, magnesium, calcium, barium, copper, and zinc. Examples thereof include zinc octylate. The curing accelerators may be used singly or in combination of two or more kinds thereof.

As described above, the resin composition according to the present embodiment may contain a silane coupling agent. The silane coupling agent may be contained in the resin composition or may be contained as a silane coupling agent covered on the inorganic filler contained in the resin composition for surface treatment in advance. Among them, it is preferable that the silane coupling agent is contained as a silane coupling agent covered on the inorganic filler for surface treatment in advance, and it is more preferable that the silane coupling agent is contained as a silane coupling agent covered on the inorganic filler for surface treatment in advance and further is also contained in the resin composition. In the case of a prepreg, the silane coupling agent may be contained in the prepreg as a silane coupling agent covered on the fibrous base material for surface treatment in advance. Examples of the silane coupling agent include those similar to the silane coupling agents used in the surface treatment of the inorganic filler described above.

The resin composition according to the present embodiment is a resin composition, which affords a cured product having a low relative dielectric constant and a low dielectric loss tangent and exhibiting excellent adhesive properties to metal foils and excellent dimensional stability.

### (Use)

The resin composition is used when a prepreg is manufactured, as described later. The resin composition is used when a resin layer included in a metal foil with resin and a film with resin is formed and when an insulating layer included in a metal-clad laminate and a wiring board is formed.

### (Production Method)

The method for producing the resin composition is not particularly limited, and examples thereof include a method in which the maleimide compound (A), the benzoxazine compound (B), and if necessary, components other than the maleimide compound (A) and the benzoxazine compound (B) are mixed together so as to have predetermined contents. Examples thereof include the method to be described later in the case of obtaining a varnish-like composition containing an organic solvent.

By using the resin composition according to the present embodiment, a prepreg, a metal-clad laminate, a wiring board, a metal foil with resin, and a film with resin can be obtained as described below.

### [Prepreg]

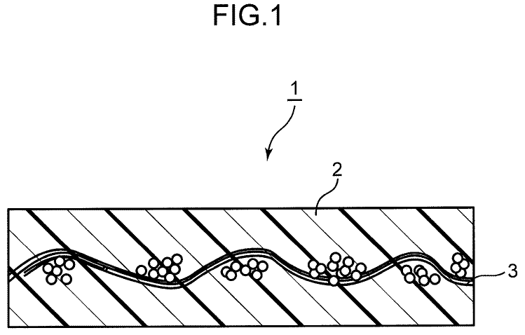

FIG. 1 is a schematic sectional view illustrating an example of a prepreg 1 according to an embodiment of the present invention.

As illustrated in FIG. 1, the prepreg 1 according to the present embodiment includes the resin composition or a semi-cured product 2 of the resin composition and a fibrous base material 3. This prepreg 1 includes the resin composition or the semi-cured product 2 of the resin composition and the fibrous base material 3 present in the resin composition or the semi-cured product 2 of the resin composition.

In the present embodiment, the semi-cured product is in a state in which the resin composition has been cured to an extent that the resin composition can be further cured. In other words, the semi-cured product is the resin composition in a semi-cured state (B-staged). For example, when a resin composition is heated, the viscosity of the resin composition first gradually decreases, then curing starts, and the viscosity gradually increases. In such a case, the semi-cured state includes a state in which the viscosity has started to increase but curing is not completed, and the like.

The prepreg to be obtained using the resin composition according to the present embodiment may include a semi-cured product of the resin composition as described above or include the uncured resin composition itself. In other words, the prepreg may be a prepreg including a semi-cured product of the resin composition (the resin composition in B stage) and a fibrous base material or a prepreg including the resin composition before being cured (the resin composition in A stage) and a fibrous base material. The resin composition or a semi-cured product of the resin composition may be one obtained by drying or heating and drying the resin composition.

When a prepreg is manufactured, the resin composition 2 is often prepared in a varnish form and used in order to be impregnated into the fibrous base material 3 which is a base material for forming the prepreg. In other words, the resin composition 2 is usually a resin varnish prepared in a varnish form in many cases. Such a varnish-like resin composition (resin varnish) is prepared, for example, as follows.

First, the respective components which can be dissolved in an organic solvent are introduced into and dissolved in an organic solvent. At this time, heating may be performed if necessary. Thereafter, components which are used if necessary but are not dissolved in the organic solvent are added to and dispersed in the solution until a predetermined dispersion state is achieved using a ball mill, a bead mill, a planetary mixer, a roll mill or the like, whereby a varnish-like resin composition is prepared. The organic solvent used here is not particularly limited as long as it dissolves the maleimide compound (A), the benzoxazine compound (B) and the like and does not inhibit the curing reaction. Specific examples thereof include toluene and methyl ethyl ketone (MEK).

Specific examples of the fibrous base material include glass cloth, aramid cloth, polyester cloth, a glass nonwoven fabric, an aramid nonwoven fabric, a polyester nonwoven fabric, pulp paper, and linter paper. When glass cloth is used, a laminate exhibiting excellent mechanical strength is obtained, and glass cloth subjected to flattening is particularly preferable. Specific examples of the flattening include a method in which glass cloth is continuously pressed at an appropriate pressure using a press roll to flatly compress the yarn. The thickness of the generally used fibrous base material is, for example, 0.01 mm or more and 0.3 mm or less. The glass fiber constituting the glass cloth is not particularly limited, and examples thereof include Q glass, NE glass, E glass, S glass, T glass, L glass, and L2 glass. The surface of the fibrous base material may be subjected to a surface treatment with a silane coupling agent. The silane coupling agent is not particularly limited, and examples thereof include a silane coupling agent having at least one selected from the group consisting of a vinyl group, an acryloyl group, a methacryloyl group, a styryl group, an amino group, and an epoxy group in the molecule.

The method for manufacturing the prepreg is not particularly limited as long as the prepreg can be manufactured. Specifically, when the prepreg is manufactured, the resin composition according to the present embodiment described above is often prepared in a varnish form and used as a resin varnish as described above.

Specific examples of the method for manufacturing the prepreg 1 include a method in which the fibrous base material 3 is impregnated with the resin composition 2, for example, the resin composition 2 prepared in a varnish form, and then dried. The fibrous base material 3 is impregnated with the resin composition 2 by dipping, coating, and the like. If necessary, the impregnation can be repeated a plurality of times. Moreover, at this time, it is also possible to finally adjust the composition and impregnated amount to the desired composition and impregnated amount by repeating impregnation using a plurality of resin compositions having different compositions and concentrations.

The fibrous base material 3 impregnated with the resin composition (resin varnish) 2 is heated under desired heating conditions, for example, at 40° C. or more and 180° C. or less for 1 minute or more and 10 minutes or less. By heating, the prepreg 1 before being cured (A-stage) or in a semi-cured state (B-stage) is obtained. By the heating, the organic solvent can be decreased or removed by being volatilized from the resin varnish.

The resin composition according to the present embodiment is a resin composition, which becomes a cured product having a low relative dielectric constant and a low dielectric loss tangent and exhibiting excellent adhesive properties to metal foils and excellent dimensional stability. In other words, when the resin composition is cured, a cured product is obtained which has a low relative dielectric constant and a low dielectric loss tangent and exhibits excellent adhesive properties to metal foils and excellent dimensional stability. For this reason, the prepreg including this resin composition or a semi-cured product of this resin composition is a prepreg, which affords a cured product having a low relative dielectric constant and a low dielectric loss tangent and exhibiting excellent adhesive properties to metal foils and excellent dimensional stability. Specifically, the relative dielectric constant of a cured product of the prepreg is preferably less than 3, more preferably less than 2.9 at a frequency of 10 GHz. The dielectric loss tangent of a cured product of the prepreg is preferably less than 0.0048, more preferably less than 0.004 at a frequency of 10 GHz. The relative dielectric constant and dielectric loss tangent here are the relative dielectric constant and dielectric loss tangent of a cured product of the prepreg at a frequency of 10 GHz, and examples thereof include the relative dielectric constant and dielectric loss tangent of a cured product of the prepreg at a frequency of 10 GHz measured by the cavity perturbation method. The dimensional change rate of a cured product of the prepreg is within 10.06%, more preferably within ±0.03% when heating is performed at 220° C. for 2 hours. The strength (copper foil peel strength) is preferably more than 0.5 N/mm, preferably 0.6 N/mm or more when the metal foil (copper foil) clad to the surface of a metal-clad laminate including a cured product of the prepreg is peeled off. For this reason, the prepreg including this resin composition or a semi-cured product of this resin composition is a prepreg, which affords a cured product having a low relative dielectric constant and a low dielectric loss tangent and exhibiting excellent adhesive properties to metal foils and excellent dimensional stability. Hence, a wiring board including an insulating layer containing a cured product having a low relative dielectric constant and a low dielectric loss tangent and exhibiting excellent adhesive properties to metal foils and excellent dimensional stability can be suitably manufactured using this prepreg.

### [Metal-Clad Laminate]

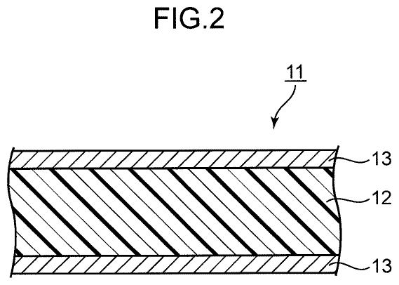

FIG. 2 is a schematic sectional view illustrating an example of a metal-clad laminate 11 according to an embodiment of the present invention.

As illustrated in FIG. 2, the metal-clad laminate 11 according to the present embodiment includes an insulating layer 12 containing a cured product of the resin composition and a metal foil 13 provided on the insulating layer 12. Examples of the metal-clad laminate 11 include a metal-clad laminate including an insulating layer 12 containing a cured product of the prepreg 1 illustrated in FIG. 1 and a metal foil 13 to be laminated together with the insulating layer 12. The insulating layer 12 may be formed of a cured product of the resin composition or a cured product of the prepreg. In addition, the thickness of the metal foil 13 varies depending on the performance and the like to be required for the finally obtained wiring board and is not particularly limited. The thickness of the metal foil 13 can be appropriately set depending on the desired purpose and is preferably, for example, 0.2 to 70 μm. Examples of the metal foil 13 include a copper foil and an aluminum foil, and the metal foil 13 may be a copper foil with carrier which includes a release layer and a carrier for the improvement in handleability in a case where the metal foil is thin.

The method for manufacturing the metal-clad laminate 11 is not particularly limited as long as the metal-clad laminate 11 can be manufactured. Specific examples thereof include a method in which the metal-clad laminate 11 is fabricated using the prepreg 1. Examples of this method include a method in which the double-sided metal foil-clad or single-sided metal foil-clad laminate 11 is fabricated by stacking one sheet or a plurality of sheets of prepreg 1, further stacking the metal foil 13 such as a copper foil on both or one of upper and lower surfaces of the prepregs 1, and laminating and integrating the metal foils 13 and prepregs 1 by heating and pressing. In other words, the metal-clad laminate 11 is obtained by laminating the metal foil 13 on the prepreg 1 and then performing heating and pressing. The heating and pressing conditions can be appropriately set depending on the thickness of the metal-clad laminate 11, the kind of the resin composition contained in the prepreg 1, and the like. For example, it is possible to set the temperature to 170 to 230° C., the pressure to 0.5 to 5 MPa, and the time to 60 to 150 minutes. The metal-clad laminate may be manufactured without using a prepreg. Examples thereof include a method in which a varnish-like resin composition is applied on a metal foil to form a layer containing the resin composition on the metal foil and then heating and pressing is performed.

The resin composition according to the present embodiment is a resin composition, which becomes a cured product having a low relative dielectric constant and a low dielectric loss tangent and exhibiting excellent adhesive properties to metal foils and excellent dimensional stability. In other words, when the resin composition is cured, a cured product is obtained which has a low relative dielectric constant and a low dielectric loss tangent and exhibits excellent adhesive properties to metal foils and excellent dimensional stability. For this reason, the metal-clad laminate including an insulating layer containing a cured product of this resin composition is a metal-clad laminate including an insulating layer containing a cured product having a low relative dielectric constant and a low dielectric loss tangent and exhibiting excellent adhesive properties to metal foils and excellent dimensional stability. Hence, a wiring board including an insulating layer containing a cured product having a low relative dielectric constant and a low dielectric loss tangent and exhibiting excellent adhesive properties to metal foils and excellent dimensional stability can be suitably manufactured using this metal-clad laminate.

### [Wiring Board]

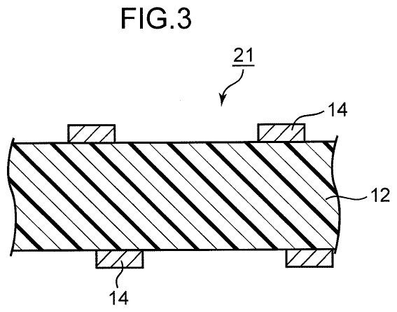

FIG. 3 is a schematic sectional view illustrating an example of a wiring board 21 according to an embodiment of the present invention.

As illustrated in FIG. 3, the wiring board 21 according to the present embodiment includes an insulating layer 12 containing a cured product of the resin composition and wiring 14 provided on the insulating layer 12. Examples of the wiring board 21 include a wiring board formed of an insulating layer 12 obtained by curing the prepreg 1 illustrated in FIG. 1 and wiring 14 which is laminated together with the insulating layer 12 and is formed by partially removing the metal foil 13. The insulating layer 12 may be formed of a cured product of the resin composition or a cured product of the prepreg.

The method for manufacturing the wiring board 21 is not particularly limited as long as the wiring board 21 can be manufactured. Specific examples thereof include a method in which the wiring board 21 is fabricated using the prepreg 1. Examples of this method include a method in which the wiring board 21, in which wiring is provided as a circuit on the surface of the insulating layer 12, is fabricated by forming wiring through etching and the like of the metal foil 13 on the surface of the metal-clad laminate 11 fabricated in the manner described above. In other words, the wiring board 21 is obtained by partially removing the metal foil 13 on the surface of the metal-clad laminate 11 and thus forming a circuit. Examples of the method for forming a circuit include circuit formation by a semi-additive process (SAP) or a modified semi-additive process (MSAP) in addition to the method described above.

The resin composition according to the present embodiment is a resin composition, which affords a cured product having a low relative dielectric constant and a low dielectric loss tangent and exhibiting excellent adhesive properties to metal foils and excellent dimensional stability. In other words, when the resin composition is cured, a cured product is obtained which has a low relative dielectric constant and a low dielectric loss tangent and exhibits excellent adhesive properties to metal foils and excellent dimensional stability. For this reason, the wiring board including an insulating layer containing a cured product of this resin composition is a wiring board including an insulating layer containing a cured product having a low relative dielectric constant and a low dielectric loss tangent and exhibiting excellent adhesive properties to metal foils and excellent dimensional stability.

The metal-clad laminate and the wiring board include the insulating layer as described above. Specifically, the insulating layer (the insulating layer included in the metal-clad laminate and the insulating layer included in the wiring board) is preferably the following insulating layer. The relative dielectric constant of the insulating layer is preferably less than 3, more preferably less than 2.9 at a frequency of 10 GHz. The dielectric loss tangent of the insulating layer is preferably less than 0.0048, more preferably less than 0.004 at a frequency of 10 GHz. The relative dielectric constant and dielectric loss tangent here are the relative dielectric constant and dielectric loss tangent of the insulating layer at a frequency of 10 GHz, and examples thereof include the relative dielectric constant and dielectric loss tangent of the insulating layer at a frequency of 10 GHz measured by the cavity perturbation method. The dimensional change rate of the insulating layer is within ±0.06%, more preferably within ±0.03% when heating is performed at 220° C. for 2 hours. The strength (copper foil peel strength) when the metal foil (copper foil) is peeled off is preferably more than 0.5 N/mm, preferably 0.6 N/mm or more in the case of a metal-clad laminate including the insulating layer. The strength (wiring peel strength) when the wiring is peeled off is preferably more than 0.5 N/mm, preferably 0.6 N/mm or more in the case of a wiring board including the insulating layer.

[Metal Foil with Resin]

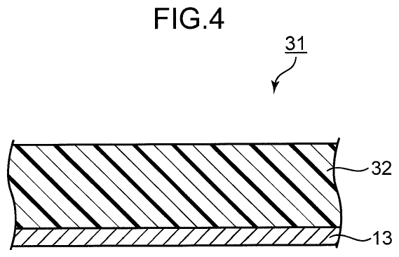

FIG. 4 is a schematic sectional view illustrating an example of a metal foil with resin 31 according to the present embodiment.

The metal foil with resin 31 according to the present embodiment includes a resin layer 32 containing the resin composition or a semi-cured product of the resin composition and a metal foil 13 as illustrated in FIG. 4. The metal foil with resin 31 includes the metal foil 13 on the surface of the resin layer 32. In other words, the metal foil with resin 31 includes the resin layer 32 and the metal foil 13 to be laminated together with the resin layer 32. The metal foil with resin 31 may include other layers between the resin layer 32 and the metal foil 13.

The resin layer 32 may contain a semi-cured product of the resin composition as described above or may contain the uncured resin composition. In other words, the metal foil with resin 31 may be a metal foil with resin including a resin layer containing a semi-cured product of the resin composition (the resin composition in B stage) and a metal foil or a metal foil with resin including a resin layer containing the resin composition before being cured (the resin composition in A stage) and a metal foil. The resin layer is only required to contain the resin composition or a semi-cured product of the resin composition and may or may not contain a fibrous base material. The resin composition or a semi-cured product of the resin composition may be one obtained by drying or heating and drying the resin composition. As the fibrous base material, those similar to the fibrous base materials of the prepreg can be used.

As the metal foil, metal foils used in metal-clad laminates or metal foils with resin can be used without limitation. Examples of the metal foil include a copper foil and an aluminum foil.

The metal foil with resin 31 may include a cover film and the like if necessary. By including a cover film, it is possible to prevent entry of foreign matter and the like. The cover film is not particularly limited, and examples thereof include a polyolefin film, a polyester film, a polymethylpentene film, and films formed by providing a release agent layer on these films.

The method for manufacturing the metal foil with resin 31 is not particularly limited as long as the metal foil with resin 31 can be manufactured. Examples of the method for manufacturing the metal foil with resin 31 include a method in which the varnish-like resin composition (resin varnish) is applied on the metal foil 13 and heated to manufacture the metal foil with resin 31. The varnish-like resin composition is applied on the metal foil 13 using, for example, a bar coater. The applied resin composition is heated under the conditions of, for example, 40° C. or more and 180° C. or less and 0.1 minute or more and 10 minutes or less. The heated resin composition is formed as the uncured resin layer 32 on the metal foil 13. By the heating, the organic solvent can be decreased or removed by being volatilized from the resin varnish.

The resin composition according to the present embodiment is a resin composition, which affords a cured product having a low relative dielectric constant and a low dielectric loss tangent and exhibiting excellent adhesive properties to metal foils and excellent dimensional stability. In other words, when the resin composition is cured, a cured product is obtained which has a low relative dielectric constant and a low dielectric loss tangent and exhibits excellent adhesive properties to metal foils and excellent dimensional stability. For this reason, the metal foil with resin including a resin layer containing this resin composition or a semi-cured product of this resin composition is a metal foil with resin including a resin layer, which affords an insulating layer containing a cured product having a low relative dielectric constant and a low dielectric loss tangent and exhibiting excellent adhesive properties to metal foils and excellent dimensional stability. Hence, this metal foil with resin can be used when manufacturing a wiring board including an insulating layer containing a cured product having a low relative dielectric constant and a low dielectric loss tangent and exhibiting excellent adhesive properties to metal foils and excellent dimensional stability. For example, by laminating the metal foil with resin on a wiring board, a multilayer wiring board can be manufactured. As a wiring board obtained using such a metal foil with resin, there is obtained a wiring board including an insulating layer containing a cured product having a low relative dielectric constant and a low dielectric loss tangent and exhibiting excellent adhesive properties to metal foils and excellent dimensional stability.

[Film with Resin]

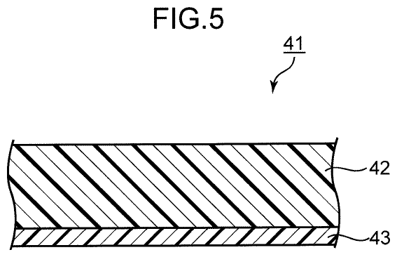

FIG. 5 is a schematic sectional view illustrating an example of a film with resin 41 according to the present embodiment.

The film with resin 41 according to the present embodiment includes a resin layer 42 containing the resin composition or a semi-cured product of the resin composition and a support film 43 as illustrated in FIG. 5. The film with resin 41 includes the resin layer 42 and the support film 43 to be laminated together with the resin layer 42. The film with resin 41 may include other layers between the resin layer 42 and the support film 43.

The resin layer 42 may contain a semi-cured product of the resin composition as described above or may contain the uncured resin composition. In other words, the film with resin 41 may be a film with resin including a resin layer containing a semi-cured product of the resin composition (the resin composition in B stage) and a support film or a film with resin including a resin layer containing the resin composition before being cured (the resin composition in A stage) and a support film. The resin layer is only required to contain the resin composition or a semi-cured product of the resin composition and may or may not contain a fibrous base material. The resin composition or a semi-cured product of the resin composition may be one obtained by drying or heating and drying the resin composition. As the fibrous base material, those similar to the fibrous base materials of the prepreg can be used.

As the support film 43, support films used in films with resin can be used without limitation. Examples of the support film include electrically insulating films such as a polyester film, a polyethylene terephthalate (PET) film, a polyimide film, a polyparabanic acid film, a polyether ether ketone film, a polyphenylene sulfide film, a polyamide film, a polycarbonate film, and a polyarylate film.

The film with resin 41 may include a cover film and the like if necessary. By including a cover film, it is possible to prevent entry of foreign matter and the like. The cover film is not particularly limited, and examples thereof include a polyolefin film, a polyester film, and a polymethylpentene film.

The support film and the cover film may be those subjected to surface treatments such as a matt treatment, a corona treatment, a release treatment, and a roughening treatment if necessary.

The method for manufacturing the film with resin 41 is not particularly limited as long as the film with resin 41 can be manufactured. Examples of the method for manufacturing the film with resin 41 include a method in which the varnish-like resin composition (resin varnish) is applied on the support film 43 and heated to manufacture the film with resin 41. The varnish-like resin composition is applied on the support film 43 using, for example, a bar coater. The applied resin composition is heated under the conditions of, for example, 40° C. or more and 180° C. or less and 0.1 minute or more and 10 minutes or less. The heated resin composition is formed as the uncured resin layer 42 on the support film 43. By the heating, the organic solvent can be decreased or removed by being volatilized from the resin varnish.

The resin composition according to the present embodiment is a resin composition, which affords a cured product having a low relative dielectric constant and a low dielectric loss tangent and exhibiting excellent adhesive properties to metal foils and excellent dimensional stability. In other words, when the resin composition is cured, a cured product is obtained which has a low relative dielectric constant and a low dielectric loss tangent and exhibits excellent adhesive properties to metal foils and excellent dimensional stability. For this reason, the film with resin including a resin layer containing this resin composition or a semi-cured product of this resin composition is a film with resin including a resin layer, which affords an insulating layer containing a cured product having a low relative dielectric constant and a low dielectric loss tangent and exhibiting excellent adhesive properties to metal foils and excellent dimensional stability. Hence, this film with resin can be used when suitably manufacturing a wiring board including an insulating layer containing a cured product having a low relative dielectric constant and a low dielectric loss tangent and exhibiting excellent adhesive properties to metal foils and excellent dimensional stability. A multilayer wiring board can be manufactured, for example, by laminating the film with resin on a wiring board and then peeling off the support film from the film with resin or by peeling off the support film from the film with resin and then laminating the film with resin on a wiring board. As a wiring board obtained using such a film with resin, there is obtained a wiring board including an insulating layer containing a cured product having a low relative dielectric constant and a low dielectric loss tangent and exhibiting excellent adhesive properties to metal foils and excellent dimensional stability.

This specification discloses techniques in various aspects as described above, and the main techniques among these are summarized below.

A resin composition according to a first aspect is a resin composition containing a maleimide compound (A) having an arylene structure bonded in meta-orientation in a molecule and a benzoxazine compound (B) having an allyl group in a molecule.

A resin composition according to a second aspect is the resin composition according to the first aspect, further containing a styrenic polymer (C) that is solid at 25° C.

A resin composition according to a third aspect is the resin composition according to the second aspect, in which the styrenic polymer (C) includes at least one selected from the group consisting of a methylstyrene (ethylene/butylene) methylstyrene block copolymer, a methylstyrene (ethylene-ethylene/propylene) methylstyrene block copolymer, a styrene isoprene block copolymer, a styrene isoprene styrene block copolymer, a styrene (ethylene/butylene) styrene block copolymer, a styrene (ethylene-ethylene/propylene) styrene block copolymer, a styrene butadiene block copolymer, a styrene isobutylene styrene block copolymer, a styrene (butadiene/butylene) styrene block copolymer, and hydrogenated products in which these are at least partly hydrogenated.

A resin composition according to a fourth aspect is the resin composition according to the second aspect, in which the styrenic polymer (C) is at least partly hydrogenated.

A resin composition according to a fifth aspect is the resin composition according to any one of the second to fourth aspects, in which a content of the maleimide compound (A) is 25 to 81 parts by mass with respect to 100 parts by mass of a sum of the maleimide compound (A), the benzoxazine compound (B), and the styrenic polymer (C).

A resin composition according to a sixth aspect is the resin composition according to any one of the second to fifth aspects, in which a content of the styrenic polymer (C) is 10 to 50 parts by mass with respect to 100 parts by mass of a sum of the maleimide compound (A), the benzoxazine compound (B), and the styrenic polymer (C).

A resin composition according to a seventh aspect is the resin composition according to any one of the first to sixth aspects, in which the maleimide compound (A) includes a maleimide compound (A1) represented by the following Formula (1).

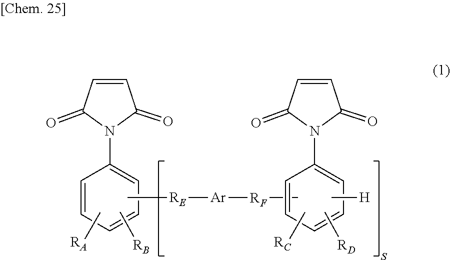

In Formula (1), Ar represents an arylene group bonded in meta-orientation, R_{A}, R_{B}, R_{c}, and R_{D} each independently represent a hydrogen atom, an alkyl group having 1 to 5 carbon atoms, or a phenyl group, R_{E} and R_{F} each independently represent an aliphatic hydrocarbon group, and s represents 1 to 5.

A resin composition according to an eighth aspect is the resin composition according to the seventh aspect, in which the maleimide compound (A1) represented by Formula (1) includes a maleimide compound (A2) represented by the following Formula (2).

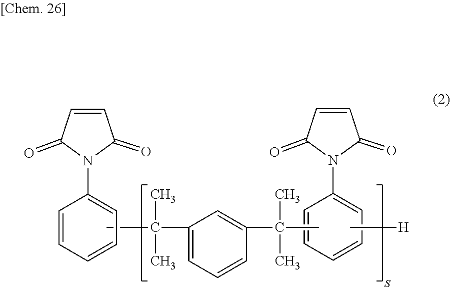

In Formula (2), s represents 1 to 5.

A resin composition according to a ninth aspect is the resin composition according to any one of the first to eighth aspects, in which the benzoxazine compound (B) includes at least one selected from a benzoxazine compound (B1) having a benzoxazine group represented by the following Formula (3) in a molecule, a benzoxazine compound (B2) having a benzoxazine group represented by the following Formula (4) in a molecule, or a benzoxazine compound (B3) having a benzoxazine group represented by the following Formula (3) and a benzoxazine group represented by the following Formula (4) in a molecule.

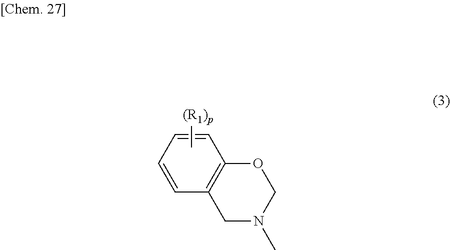

In Formula (3), R₁ represents an allyl group, and p represents 1 to 4.

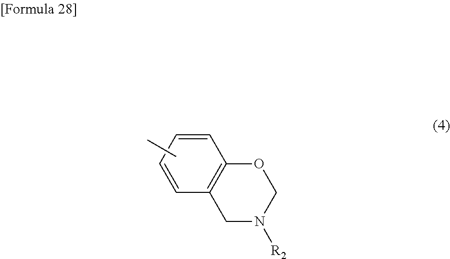

In Formula (4), R₂ represents an allyl group.

A resin composition according to a tenth aspect is the resin composition according to the ninth aspect, in which the benzoxazine compound (B1) includes a benzoxazine compound (B4) represented by the following Formula (5).

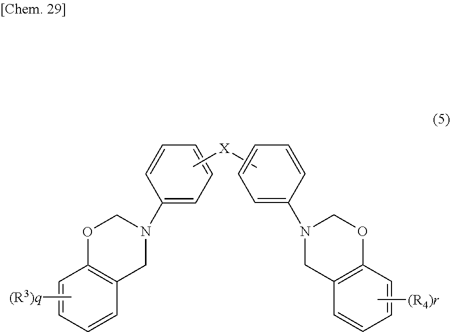

In Formula (5), R₃ and R₄ represent an allyl group, X represents an ether bond or an alkylene group, and q and r each independently represent 1 to 4.

A resin composition according to an eleventh aspect is the resin composition according to any one of the first to tenth aspects, in which a content of the maleimide compound (A) is 50 to 90 parts by mass with respect to 100 parts by mass of a sum of the maleimide compound (A) and the benzoxazine compound (B).

A resin composition according to a twelfth aspect is the resin composition according to any one of the first to eleventh aspects, further containing an inorganic filler.

A resin composition according to a thirteenth aspect is the resin composition according to any one of the second to sixth aspects, further containing an inorganic filler in which a content of the inorganic filler is 10 to 150 parts by mass with respect to 100 parts by mass of a sum of the maleimide compound (A), the benzoxazine compound (B), and the styrenic polymer (C).

A prepreg according to a fourteenth aspect is a prepreg including the resin composition according to any one of the first to thirteenth aspects or a semi-cured product of the resin composition; and a fibrous base material.

A film with resin according to a fifteenth aspect is a film with resin including a resin layer containing the resin composition according to any one of the first to thirteenth aspects or a semi-cured product of the resin composition; and a support film.

A metal foil with resin according to a sixteenth aspect is a metal foil with resin including a resin layer containing the resin composition according to any one of the first to thirteenth aspects or a semi-cured product of the resin composition; and a metal foil.

A metal-clad laminate according to a seventeenth aspect is a metal-clad laminate including an insulating layer containing a cured product of the resin composition according to any one of the first to thirteenth aspects; and a metal foil.

A metal-clad laminate according to an eighteenth aspect is a metal-clad laminate including an insulating layer containing a cured product of the prepreg according to the fourteenth aspect; and a metal foil.

A wiring board according to a nineteenth aspect is a wiring board including an insulating layer containing a cured product of the resin composition according to any one of the first to thirteenth aspects; and a wiring.

A wiring board according to a twentieth aspect is a wiring board including an insulating layer containing a cured product of the prepreg according to the fourteenth aspect; and a wiring.

According to the present invention, it is possible to provide a resin composition, which affords a cured product having a low dielectric constant and a low dielectric loss tangent and exhibiting excellent adhesive properties to metal foils and excellent dimensional stability. Furthermore, according to the present invention, it is possible to provide a prepreg, a film with resin, a metal foil with resin, a metal-clad laminate, and a wiring board each obtained using the resin composition.

Hereinafter, the present invention will be described more specifically with reference to examples, but the scope of the present invention is not limited thereto.

### EXAMPLES

### Examples 1 to 6 and Comparative Examples 1 and 2

The respective components to be used when preparing a resin composition in the present examples will be described.

### (Maleimide Compound)

Maleimide compound-1: Maleimide compound having arylene structure bonded in meta-orientation in molecule (maleimide compound represented by Formula (2), solid component in MIR-5000-60T manufactured by Nippon Kayaku Co., Ltd.)

Maleimide compound-2: Maleimide compound not having arylene structure bonded in meta-orientation in molecule (polyphenylmethane maleimide, BMI-2300 manufactured by Daiwa Kasei Industry Co., Ltd.)

### (Benzoxazine Compound)

Benzoxazine compound: Benzoxazine compound having allyl group in molecule (benzoxazine compound represented by Formula (5), where X is methylene group and q and r are 1, ALPd manufactured by SHIKOKU CHEMICALS CORPORATION)

### (Other Components)

Modified PPE: Modified polyphenylene ether compound (modified polyphenylene ether obtained by modifying terminal hydroxyl group of polyphenylene ether with methacryloyl group, SA 9000 manufactured by SABIC Innovative Plastics, weight average molecular weight Mn: 2300)

TAIC: Triallyl isocyanurate (TAIC manufactured by Nihon Kasei Co., Ltd.)

### (Styrenic Polymer)

Styrenic polymer-1: Styrenic polymer of which part is hydrogenated (partly hydrogenated) (styrene (butadiene/butylene) styrene copolymer, Tuftec P1500 manufactured by Asahi Kasei Corporation)

Styrenic polymer-2: Non-hydrogenated styrenic polymer (styrene butadiene styrene copolymer, Asaprene T437 manufactured by Asahi Kasei Corporation)

### (Reaction Initiator)

PBP: α,α′-Di(t-butylperoxy)diisopropylbenzene (Perbutyl P (PBP) manufactured by NOF CORPORATION)

### (Curing Accelerator)

2E4MZ: 2-Ethyl-4-methylimidazole (2E4MZ manufactured by SHIKOKU CHEMICALS CORPORATION)

### (Inorganic Filler)

Silica: Silica particles subjected to surface treatment with silane coupling agent having vinyl group in molecule (K180SV-C1 manufactured by Admatechs Company Limited)

### [Preparation Method]

First, the respective components other than the inorganic filler were added to and mixed in toluene at the compositions (parts by mass) shown in Table 1 so that the solid concentration was 30% by mass. The mixture was stirred for 60 minutes. Thereafter, the inorganic filler was added to the obtained liquid, and dispersed using a bead mill. By doing so, a varnish-like resin composition (varnish) was obtained.

Next, a glass cloth (#1067 type, NE glass manufactured by Nitto Boseki Co., Ltd.) was impregnated with the obtained varnish, and then heated and dried at 100 to 160° C. for about 2 to 8 minutes to obtain a prepreg. At that time, the thickness of the prepreg after curing was adjusted to be about 76 μm (the content of organic components in the resin composition was about 74% by mass).

### (Evaluation Substrate 1)

Then, four sheets of each of the obtained prepregs were stacked, a 1.5 μm thick copper foil with a 18 μm thick carrier foil (MT18FL 1.5 manufactured by Mitsui Mining & Smelting Co., Ltd.) was disposed on both sides thereof to obtain a body to be pressed, and the body to be pressed was heated and pressed at a temperature of 220° C. and a pressure of 2 MPa for 2 hours, thereby obtaining a copper foil-clad laminate (metal-clad laminate) having a thickness of about 0.3 mm and having copper foil pasted to both surfaces. This obtained copper foil-clad laminate was designated as an evaluation substrate 1.

### (Evaluation Substrate 2)

A copper foil-clad laminate (metal-clad laminate) having a thickness of about 0.15 mm was obtained by a method similar to that of manufacturing the evaluation substrate 1 except that the number of prepreg sheets to be stacked was changed from 4 to 2 and the copper foil was changed from the 1.5 μm thick copper foil with a 18 μm thick carrier foil (MT18FL 1.5 manufactured by Mitsui Mining & Smelting Co., Ltd.) to a 12 μm thick copper foil (3EC-VLP manufactured by Mitsui Mining & Smelting Co., Ltd.). This obtained copper foil-clad laminate was designated as an evaluation substrate 2.

The evaluation substrates fabricated as described above were evaluated by the methods described below.

### [Dielectric Properties (Relative Dielectric Constant and Dielectric Loss Tangent)]

The copper foil was removed from the evaluation substrate 1 by etching. The substrate thus obtained was used as a test piece, and the relative dielectric constant and dielectric loss tangent at 10 GHz were measured by the cavity perturbation method. Specifically, the relative dielectric constant (Dk) and dielectric loss tangent (Df) of the test piece at 10 GHz were measured using a network analyzer (N5230A manufactured by Agilent Technologies, Inc.). When the relative dielectric constant acquired by the measurement was less than 3, it was determined as “acceptable”. When the dielectric loss tangent acquired by the measurement was less than 0.0048, it was determined as “acceptable”.

### [Copper Foil Peel Strength]

The carrier foil was peeled off from the evaluation substrate 1, and the electroless copper plating treatment and electrolytic copper plating treatment were conducted to adjust the thickness of the metal foil (copper foil) to 35 μm. The copper foil was peeled off from this substrate having a copper foil thickness of 35 μm, and the peel strength at that time was measured in conformity with JIS C 6481 (1996). Specifically, a pattern having a width of 10 mm and a length of 100 mm was formed on the evaluation substrate, the copper foil was peeled off at a speed of 50 mm/min using a tensile tester, and the peel strength (N/mm) at that time was measured. When the copper foil peel strength acquired by the measurement was more than 0.5 N/mm, it was determined as “acceptable”.

### [Glass Transition Temperature (Tg)]

Using an unclad substrate obtained by removing the copper foil from the evaluation substrate 1 by etching as a test piece, the Tg of the cured product of the resin composition was measured using a viscoelastic spectrometer “DMS6100” manufactured by Seiko Instruments Inc. At this time, dynamic viscoelasticity measurement (DMA) was performed with a tensile module at a frequency of 10 Hz, and the temperature at which tan δ was maximized when the temperature was raised from room temperature to 340° C. at a rate of temperature rise of 5° C./min was taken as Tg (° C.). When the glass transition temperature acquired by the measurement was more than 260° C., it was determined as “acceptable”.

### [Dimensional Stability: Dimensional Change Rate]

An unclad substrate obtained by removing the copper foil from the evaluation substrate 2 by etching was cut to have a length of 25 mm and a width of 5 mm. This cut unclad substrate was used as a test piece, and this test piece was heated at 220° C. for 2 hours. At that time, the distance between two predetermined points on the test piece in the warp direction of the glass cloth both before the heating and after the heating was measured. For example, the length (150 mm) of the test piece was taken as the length before heating, and the length of the test piece after heating was taken as the length after heating. Then, the ratio (%) [(length after heating−length before heating)/length before heating×100] of the value acquired by subtracting the length before heating from the length after heating to the length before heating was calculated, and this ratio (%) was taken as the dimensional change rate. When the acquired dimensional change rate was within ±0.06% (namely, −0.06% or more and 0.06% or less), it was determined as “acceptable”.

The results of each evaluation are shown in Table 1.

TABLE 1

| | | | Examples | | | | | | Comparative Example | |
|---|---|---|---|---|---|---|---|---|---|---|
| | | | 1 | 2 | 3 | 4 | 5 | 6 | 1 | 2 |
| Composition | Maleimide | Maleimide | 70 | 80 | 56 | 56 | 56 | 56 | — | — |
| (parts | compound | compound-1 | | | | | | | | |
| by mass) | | Maleimide | — | — | — | — | — | — | 70 | — |
| | | compound-2 | | | | | | | | |
| | Benzoxazine compound | | 30 | 20 | 14 | 14 | 14 | 14 | 30 | — |
| | Modified PPE | | — | — | — | — | — | — | — | 70 |
| | TAIC | | — | — | — | — | — | — | — | 30 |
| | Styrenic polymer | Styrenic | — | — | 30 | 30 | 30 | — | — | — |
| | | polymer-1 | | | | | | | | |
| | | Styrenic | — | — | — | — | — | 30 | — | — |
| | | polymer-2 | | | | | | | | |
| | Reaction initiator | PBP | 1 | 1 | 1 | 1 | 1 | 1 | 1 | 3 |
| | Curing accelerator | 2E4MZ | 1 | 1 | 1 | 1 | 1 | 1 | 1 | — |
| | Inorganic filler | Silica | — | — | — | 20 | 40 | 20 | — | — |
| Evaluation | Dielectric | Relative dielectric | 2.94 | 2.95 | 2.64 | 2.90 | 2.93 | 2.92 | 3.04 | 2.85 |
| | properties | constant | | | | | | | | |
| | | Dielectric loss | 0.0047 | 0.0041 | 0.0030 | 0.0030 | 0.0031 | 0.0034 | 0.0048 | 0.0050 |
| | | tangent | | | | | | | | |

| | | | | | | | | |
|---|---|---|---|---|---|---|---|---|
| Copper foil peel strength (N/mm) | 0.60 | 0.52 | 1.07 | 1.09 | 0.98 | 0.89 | 0.52 | 0.12 |
| Glass transition temperature (° C.) | 272 | 334 | 328 | 329 | 329 | 326 | 329 | 283 |
| Dimensional change rate (%) | −0.004 | 0.001 | −0.005 | −0.026 | −0.011 | −0.060 | 0.023 | −0.064 |

As can be seen from Table 1, in a case of containing the maleimide compound (A) and the benzoxazine compound (B) (Examples 1 to 6), there have been obtained resin compositions, which become cured products having a lower dielectric constant and a lower dielectric loss tangent and exhibiting superior adhesive properties to metal foils and superior dimensional stability compared to other cases (a case where a maleimide compound different from the maleimide compound (A) is contained: Comparative Example 1, and a case where the maleimide compound (A) and the benzoxazine compound (B) are not contained but a modified polyphenylene ether compound and triallyl isocyanurate are contained: Comparative Example 2).

This application is based on Japanese Patent Application No. 2022-035374 filed on Mar. 8, 2022, and the contents of which are included in the present application.

In order to express the present invention, the present invention has been described above appropriately and sufficiently through the embodiments. However, it should be recognized by those skilled in the art that changes and/or improvements of the above-described embodiments can be readily made. Accordingly, changes or improvements made by those skilled in the art shall be construed as being included in the scope of the claims unless otherwise the changes or improvements are at the level which departs from the scope of the appended claims.

### INDUSTRIAL APPLICABILITY

According to the present invention, there is provided a resin composition, which affords a cured product having a low dielectric constant and a low dielectric loss tangent and exhibiting excellent adhesive properties to metal foils and excellent dimensional stability. In addition, the present invention provides a prepreg, a film with resin, a metal foil with resin, a metal-clad laminate, and a wiring board which are obtained using the resin composition.

1. A resin composition comprising:
a maleimide compound (A) having an arylene structure bonded in meta-orientation in a molecule; and
a benzoxazine compound (B) having an allyl group in a molecule.

2. The resin composition according to claim 1, further comprising a styrenic polymer (C) that is solid at 25° C.

3. The resin composition according to claim 2, wherein the styrenic polymer (C) includes at least one selected from the group consisting of a methylstyrene (ethylene/butylene) methylstyrene block copolymer, a methylstyrene (ethylene-ethylene/propylene) methylstyrene block copolymer, a styrene isoprene block copolymer, a styrene isoprene styrene block copolymer, a styrene (ethylene/butylene) styrene block copolymer, a styrene (ethylene-ethylene/propylene) styrene block copolymer, a styrene butadiene block copolymer, a styrene isobutylene styrene block copolymer, a styrene (butadiene/butylene) styrene block copolymer, and hydrogenated products in which these are at least partly hydrogenated.

4. The resin composition according to claim 2, wherein the styrenic polymer (C) is at least partly hydrogenated.

5. The resin composition according to claim 2, wherein a content of the maleimide compound (A) is 25 to 81 parts by mass with respect to 100 parts by mass of a sum of the maleimide compound (A), the benzoxazine compound (B), and the styrenic polymer (C).

6. The resin composition according to claim 2, wherein a content of the styrenic polymer (C) is 10 to 50 parts by mass with respect to 100 parts by mass of a sum of the maleimide compound (A), the benzoxazine compound (B), and the styrenic polymer (C).

7. The resin composition according to claim 1, wherein the maleimide compound (A) includes a maleimide compound (A1) represented by the following Formula (1): 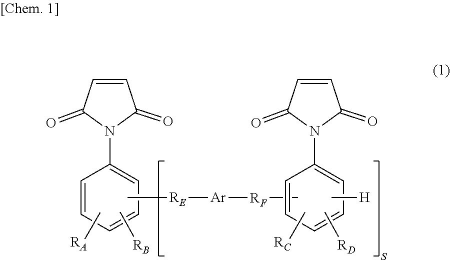
[in Formula (1), Ar represents an arylene group bonded in meta-orientation, R_{A}, R_{B}, R_{c}, and R_{D} each independently represent a hydrogen atom, an alkyl group having 1 to 5 carbon atoms, or a phenyl group, R_{E} and R_{F} each independently represent an aliphatic hydrocarbon group, and s represents 1 to 5].

8. The resin composition according to claim 7, wherein the maleimide compound (A1) represented by Formula (1) includes a maleimide compound (A2) represented by the following Formula (2): 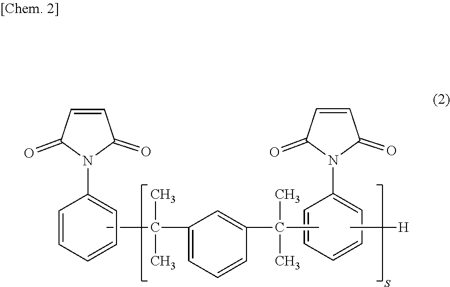
[in Formula (2), s represents 1 to 5].

9. The resin composition according to claim 1, wherein the benzoxazine compound (B) includes at least one selected from a benzoxazine compound (B1) having a benzoxazine group represented by the following Formula (3) in a molecule, a benzoxazine compound (B2) having a benzoxazine group represented by the following Formula (4) in a molecule, or a benzoxazine compound (B3) having a benzoxazine group represented by the following Formula (3) and a benzoxazine group represented by the following Formula (4) in a molecule: 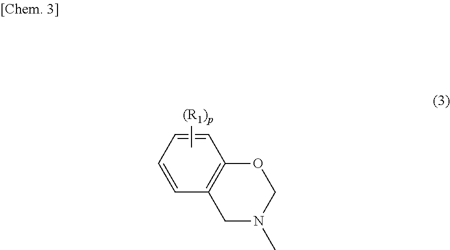
[in Formula (3), R₁ represents an allyl group, and p represents 1 to 4], and 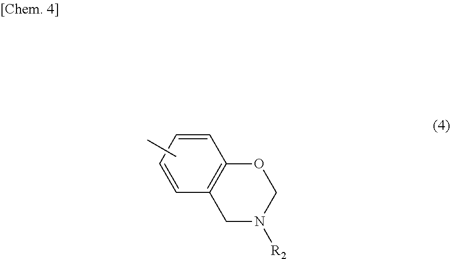
[in Formula (4), R₂ represents an allyl group].

10. The resin composition according to claim 9, wherein the benzoxazine compound (B1) includes a benzoxazine compound (B4) represented by the following Formula (5): 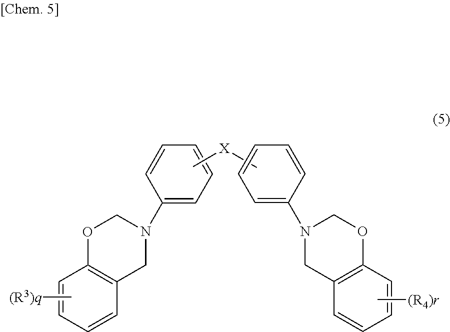
[in Formula (5), R₃ and R₄ represent an allyl group, X represents an ether bond or an alkylene group, and q and r each independently represent 1 to 4].

11. The resin composition according to claim 1, wherein a content of the maleimide compound (A) is 50 to 90 parts by mass with respect to 100 parts by mass of a sum of the maleimide compound (A) and the benzoxazine compound (B).

12. The resin composition according to claim 1, further comprising an inorganic filler.

13. The resin composition according to claim 2, further comprising an inorganic filler, wherein
a content of the inorganic filler is 10 to 150 parts by mass with respect to 100 parts by mass of a sum of the maleimide compound (A), the benzoxazine compound (B), and the styrenic polymer (C).

14. A prepreg comprising: the resin composition according to claim 1 or a semi-cured product of the resin composition; and a fibrous base material.

15. A film with resin comprising: a resin layer containing the resin composition according to claim 1 or a semi-cured product of the resin composition; and a support film.

16. A metal foil with resin comprising: a resin layer containing the resin composition according to claim 1 or a semi-cured product of the resin composition; and a metal foil.

17. A metal-clad laminate comprising: an insulating layer containing a cured product of the resin composition according to claim 1; and a metal foil.

18. A metal-clad laminate comprising: an insulating layer containing a cured product of the prepreg according to claim 14; and a metal foil.

19. A wiring board comprising: an insulating layer containing a cured product of the resin composition according to claim 1; and a wiring.

20. A wiring board comprising: an insulating layer containing a cured product of the prepreg according to claim 14; and a wiring.
